(19) United States
(12) Patent Application Publication
(10) Pub. No.: US 2025/0226212 A1
(43) Pub. Date: Jul. 10, 2025

(54) Fabrication and processing of graphene electronic devices on Silicon with a SiO2 passivation layer

(71) Applicant: Archer Materials Limited, Adelaide (AU)

(72) Inventors: Alexander James PORKOVICH, Adelaide (AU); Mohammad CHOUCAIR, Adelaide (AU)

(21) Appl. No.: 18/850,697

(22) PCT Filed: Mar. 31, 2023
(86) PCT No.: PCT/AU2023/050251

§ 371 Date: Sep. 25, 2024

(30) Foreign Application Priority Data
Mar. 31, 2022 (AU) 2022900845

(51) Int. Cl. H01L 21/02; H10D 30/01; H10D 30/47; H10D 62/80

(52) U.S. Cl. CPC H01L 21/02334; H01L 21/0206; H01L 21/02115; H01L 21/02271; H01L 21/0234; H01L 21/02351; H10D 30/017; H10D 30/481; H10D 62/882

(57) ABSTRACT

The present invention broadly relates to the fabrication and processing of graphene electronic devices on silicon which comprise a silicon dioxide passivation layer.

### FIELD

The present invention broadly relates to the fabrication and processing of graphene electronic devices on silicon which comprise a silicon dioxide passivation layer.

### BACKGROUND

Graphene is a highly promising material for use in electronic devices, specifically graphene field effect transistors (gFETs). This includes analogue applications, such as gas and biological molecule sensors, and digital applications (at certain low dimensional sizes). At this point however, graphene is yet to truly pass beyond lab scale applications, due to a lack of process integration into traditional silicon (Si) wafer production lines. The main issues with graphene processing and integration with Si are: transferring graphene from growth substrates, protecting the graphene during fabrication, and degradation of electrical performance of graphene caused by the processing of polymer resists used in lithography.

Graphene is not typically grown on SiO₂ substrates. This is an issue in the fabrication of graphene-based semiconductor devices as many electronic devices integrated into silicon technology (i.e. integrated circuits and sensors) require a thin layer of SiO₂ to act as an insulating layer. This layer is imperative in activating the field-effect which is responsible for allowing materials to function as transistors. Since direct growth of graphene on silicon substrates is not easily realisable, graphene is usually synthesised and then transferred to the SiO₂ surface. This includes graphene layers removed from graphite, graphene synthesised via chemical vapour deposition (CVD) and chemically synthesised and separated graphene dispersed in solution. Of these, exfoliated graphene from graphite typically produces the best quality of graphene, however, the methods are not industrially scalable and are mostly confined to research applications. Both CVD and chemically synthesised graphene are more suitable to fabrication scale-up. CVD generally involves growth on a metallic catalyst (either copper or nickel) and transfer to the Si wafer. Many transfer processes are in use, which either leave chemical residues or defects (sometimes both) negatively effecting the electronic properties. Despite this, CVD is widely regarded as a process advantageous in graphene fabrication as it results in the repeatability and reproducibility of homogenous mono-to-few layer graphene batch-to-batch.

To effectively integrate CVD grown graphene into gFETs, a method needs to be developed to prevent undesirable defects and delamination of graphene while retaining electronic properties. These two properties are inextricably linked, as broken sp² bonds in graphene (either through vacancy or sp³ bond defects) will result in decreased electronic transport through the graphene surface. Pristine graphene with no defects and no substrate bonds only scatters electrons through phonon interactions. However, once the graphene is contacted from above (e.g., impurities disrupting the sp² bonds, or passivation layers) or below (e.g., substrate interactions), these impurities also scatter electrons, decreasing the electronic transport. Recent models have been able to link electron mobility and electron transport directly to defect density, allowing the calculation of defects through electronic measurements through the equation

$$μ = α / {η}_{0}$$

where μ is the electron mobility, n₀ is the defect density, and α is 20·e²/h (which is approximately the value of a sample's conductivity). Therefore, a decrease in defects can be directly measured electronically as an improvement in carrier mobility (i.e. lower sheet resistance).

There are a few methods of quantifying the number of defects on a graphene sheet. The most powerful is Raman spectroscopy. In addition to determining the number of graphene sheets on the surface, this technique can determine whether defects are present and in what form. The main form of defects are vacancy defects of missing carbon atoms in the lattice, and sp3 defects where carbon atoms in the graphene have bonded to another atom on the surface interfering with the delocalised sp2 bonding of the graphene lattice. The standard spectrum of graphene shows a graphitic peak at approximately 1600 cm⁻¹ (G) and a 2D band at approximately 2650 cm⁻¹. Additional peaks at approximately 1360 cm⁻¹ (D) and approximately 1610 cm⁻¹ (D′) carry information about the population type of defect (the intensity of the peaks indicating number of defects, and the ratio between the intensities of D and D′ demonstrating the nature of defects). Information from Raman on graphene usually comes from the ratio of peak heights or areas. If there are D/D′ ratios greater than 10, particularly around 13, the defects will likely be due to sp³ defects. Ratios around 7 equate to vacancy defects (important to prevent the removal from graphene) and ratios around 3.5 are grain boundaries or dislocations of the lattice. The relative height of the D peak is suggestive of how many defects are present. The D′ peak is also quite close to the G peak, meaning if defects increase there will be changes to the full width half maximum (FWHM) before the D′ peak is fully seen

In the art the skilled person is trying to prevent defects in general (i.e. keep D and D′ small to non-existent) if there are defects, the ratio between D and D′ should be as low as small as possible to ensure that it is just discontinuity or small gaps. If the defects are related to sp³ then larger problems can occur during processing resulting in wide scale delamination.

X-ray photoelectron spectroscopy (XPS) is another method of determining the number of defects in graphene. This can be done through examination of the core carbon Is spectra. Carbon to carbon sp² bonds found in graphene have lower binding energies, approximately 284 eV, when compared to sp³ bonds (284.8 eV for carbon-carbon/hydrogen and between approximately 286 and 289 eV for carbon to other elements). In terms of the XPS, the skilled person would expect to see a convolution of the 284.8 and 284 peaks. 284.8 will dominate no matter due to the layer of adventitious carbon (which can only be removed in vacuum via ion bombardment which will remove graphene). XPS should hopefully show less in 286 and 289 peaks due to other carboxyl groups. Additionally, XPS can determine and quantify the presence of other elements on the sample, providing a higher degree of precision in isolating what the chemical defects are, and how many are present. XPS of the valence band can be used to calculate information about the bandgap, allowing direct linking of the chemical and electronic properties of the graphene.

Direct observation and quantification of defects is also possible through microscopy of the graphene surface. At high magnifications, defects can be observed with optical microscopes as changes in colour. These defects can be countered in terms of the ratio of the defective area of graphene to the total area of graphene. For instance, it is observed that for the present method the skilled person can expect to see about 5% less defects relative to comparable methods used in the prior art.

There exist some strategies to reduce defects and delamination, including patterning with metals (specifically Ti and Au) and cleaning graphene (using vacuum heating and laser and electron beams). While metallic protection is effective in protection during processing, post process packaging including plasma and laser dicing require further photoresist-based lithography, which cannot be protected against using these processes post fabrication. Simultaneously, the energy intensive based cleaning methods tend to induce more undesirable defects while removing residue.

For full integration of gFETs into silicon technology, fabrication of gFETs must be compatible with cleanroom environments. This means developing lithography methods compatible with photo or electron polymer resists, and using pristine graphene with in-plane crystallinity on Si (i.e. CVD). Further developing gFETs into sensing platforms (particularly biosensors utilising liquid gating) requires electrode passivation and isolation to reduce crosstalk. This introduces another layer of complexity (and lithography) beyond just fabricating graphene electrodes. Therefore, even if sacrificial metal layers are used to protect graphene during fabrication, the issue of reliably removing polymer resist and residue will also need to be solved.

The present invention seeks to overcome one or more of the current shortcomings in the art.

### SUMMARY OF THE INVENTION

The present invention provides methods of gFET fabrication suitable for an ISO 5 cleanroom environment and includes three cleaning processing steps. Si covered with a complete mono-to-few layer graphene (from 1 to 3) film (produced from CVD) was used for fabrication. This (layer number) is important on the electronic structure as well, as with graphene it is well studied that with more than one layer a bandgap is introduced. During gFET fabrication, the steps used can introduce contaminants and defects to the graphene surface which remain and subsequently result in delamination of the graphene layer. These contaminants and defects remain attached to the graphene surface and the resist layer used to transfer the graphene on to the Si surface, such that removal of the resist results in removal of both the contaminants and attached graphene. Since graphene underlying these contaminants is removed, delamination occurs thus leaving an incomplete layer of graphene.

The present inventors have found that the methods disclosed herein minimise or prevent the delamination of graphene that is deposited on a substrate. It has also been found that the methods disclosed herein can be used to fabricate a graphene field effect transistor (gFET).

In relation to the present method, first, the graphene on Si is rinsed with a methylbenzene (in one case, xylene), second rinsed with a ketone (in one case, acetone), and finally rinsed in an alcohol (in one case, isopropyl alcohol (IPA)). Additionally, the methylbenzene is used in the removal of the polymer resist (e.g. PMMA) following lithography, followed by the cleaning with ketone and alcohol. The present inventors have found that first cleaning with a methylbenzene such as xylene, is beneficial in preventing graphene delamination during resist removal post lithography. This is primarily attributed to the removal of contaminants and defects related to amorphous carbon deposit introduced during CVD of the graphene layer.

Accordingly, in one aspect the invention provides a method of minimising or preventing graphene delamination and/or reducing defects on a graphene layer deposited on SiO₂/Si substrate, said method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited layer with a methylbenzene;
iv) cleaning the layer after step iii) with a ketone; and
v) cleaning the layer after step iv) with an alcohol.

In a second aspect the invention further provides a method of fabricating a graphene field effect transistor (gFET) comprising a graphene layer deposited on SiO₂/Si substrate and wherein said gFET is characterised with at least one drain, source and gate electrodes, the method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited later with a methylbenzene;
iv) cleaning the layer after step iii) with a ketone;
v) cleaning the layer after step iv) with an alcohol;
vi) depositing a polymer resist on the layer after step v);
vii) defining areas where graphene will remain on wafer substrate using e-beam lithography;
viii) removing unneeded graphene using O₂ plasma etching;
ix) cleaning off any remaining resist using a methylbenzene;
x) cleaning the remaining graphene layer with a ketone;
xi) cleaning the graphene layer after step x) with an alcohol;
xii) depositing an adhesive layer comprising Ti or Cr on to the graphene surface layer after step xi);
xiii) depositing a metal electrode material layer on to the adhesive layer after step xii); and
xiv) stripping the metal layer of step xiii) to form the gFET which comprises at least one each of a drain, source and gate electrodes.

In respect to the two above aspects in certain embodiments the methylbenzene is selected from xylene (ortho-xylene, meta-xylene, or para-xylene), toluene, hemellitene (1,2,3-trimethylbenzene), mesitylene (1,3,5-trimethylbenzene), pseudocumene (1,2,4-trimethylbenzene), prehnitene (1,2,3,4-tetramethylbenzene), isodurene (1,2,3,5-tetramethylbenzene), durene (1,2,4,5-tetramethylbenzene), and hexamethylbenzene. In an embodiment commercially purchased methylbenzene is sufficient. In an embodiment the commercially purchased methylbenzene contains minimal (i.e., less than 1%) metallic impurities. In a preferred embodiment, the methylbenzene is a xylene.

In respect to the two above aspects in certain embodiments the ketone is selected from acetone, ethyl acetate, cyclohexanone, methyl ethyl ketone, and diacetone. In an embodiment commercially purchased ketone is sufficient. In an embodiment the commercially purchased ketone contains minimal (i.e., less than 1%) metallic impurities. In a preferred embodiment, the ketone is acetone.

In respect to the two above aspects in certain embodiments the alcohol is selected from isopropanol (IPA), ethanol, n-propanol, n-butanol, isobutanol, tert-butanol, and n-pentanol. In an embodiment commercially purchased alcohol is sufficient. In an embodiment the commercially purchased alcohol contains minimal (i.e., less than 1%) metallic impurities. In a preferred embodiment, the alcohol is isopropanol.

In certain embodiments of the first or second aspects, the one or more of the cleaning steps may be independently performed one or more times.

In certain embodiments, the polymer resist is selected from the group consisting of poly(methyl methacrylate) (PMMA), poly(α-methyl styrene-co-α-chloroacrylate methylester) (CSAR62), ZEP520, and maN2403.

In an embodiment of the first aspect, the method comprises the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited layer with a xylene;
iv) cleaning the layer after step iii) with acetone; and
v) cleaning the layer after step iv) with isopropanol.

In an embodiment of the second aspect, the method comprises the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited later with a xylene;
iv) cleaning the layer after step iii) with acetone;
v) cleaning the layer after step iv) with isopropanol;
vi) depositing a polymer resist on the layer after step v);
vii) defining areas where graphene will remain on wafer substrate using e-beam lithography;
viii) removing unneeded graphene using O₂ plasma etching;
ix) cleaning off any remaining polymer resist using a xylene;
x) cleaning the remaining graphene layer with acetone;
xi) cleaning the graphene layer after step x) with isopropanol;
xii) depositing an adhesive layer comprising Ti or Cr on to the graphene surface layer after step xi);
xiii) depositing a metal electrode material layer on to the adhesive layer after step xii); and
xiv) stripping the metal layer of step xiii) to form the gFET which comprises at least one each of a drain, source and gate electrodes.

The methods disclosed herein define steps that provide a graphene layer where delamination of the layer is minimised. Accordingly, these methods may be used in the preparation of an electronic device, where the fabrication of the electronic device includes the steps in the methods disclosed herein. In certain embodiments, the electronic device may be selected from the group consisting of a graphene-based electronic circuit, an electronic sensor, an analog circuit, a semiconductor chip and a microfluidic delivery system. In certain embodiments, the graphene-based electronic circuit comprises a graphene field effect transistor (gFET). In other embodiments, the electronic sensor is a sensor for a gas or a biological molecule. In a particular embodiment, the analog circuit is an amplifier, an oscillator or a mixed circuit. In certain embodiments, the microfluidic delivery system delivers a gas and/or a biological molecule.

### FIGURES

FIG. 1. gFETs made with two step acetone and IPA clean and acetone lift-off. The graphene is torn over a wide area, exposing SiO₂ (low contrast area/light purple colour). This form of cleaning results in graphene delamination and tearing (high contrast regions) with PMMA removal.

FIG. 2. Resistance measurements of the graphene covered Si die seen in FIG. 1. The overlaid circle on the left of the image highlights the location of the die as well as the location of the probes, while the overlaid circle on the top right of the image highlights the output value of the resistance measurement on the multimeter. The value on the multimeter is too high for the range to measure, indicating a resistance over 100 MΩ (effectively an electrical insulator) far larger than expected for graphene.

FIG. 3. Bare graphene on SiO₂ 1 cm×1 cm die cleaned with acetone and IPA step before being coated in PMMA and cured. PMMA was then removed, and the resulting die was imaged at the a) centre and b) edge.

FIG. 4. Reasons for the delamination of graphene. A piece of bare Si (high contrast rectangle/blue) with a SiO₂ (low contrast rectangle/grey) passivation layer is cleaned for graphene transfer (a). Graphene (dotted line) is transferred to the surface using a polymer (generally PMMA), after which the PMMA is removed (b). Contaminants, defects and amorphous carbon from synthesis and transfer remain on the graphene surface (c). These defects and contaminants are not removed with the acetone-IPA clean (d), and when PMMA is deposited and cured, these points anchor the graphene to the PMMA (c). Subsequently, when PMMA is removed, the anchoring points remove the underlying graphene (f).

FIG. 5. Bare graphene on SiO₂ 1 cm×1 cm die cleaned with xylene, acetone and IPA step before being coated in PMMA and cured. PMMA was then removed, and the resulting die was imaged at the a) centre and b) edge.

FIG. 6. Raman spectroscopy of graphene sample a) before cleaning and PMMA deposition and b) following three-step washing, PMMA deposition, curing and removal with three-step washing. G bands positioned at 1598 cm⁻¹ and 2D at 2650 cm⁻¹. The D′ peak is also quite close to the G peak, meaning if defects increase there will be changes to the full width half maximum (FWHM) before the D′ peak is fully seen. For instance, for the present invention the precleaned graphene had a G peak FWHM of 7.8 cm⁻¹, while post cleaning, based on the present invention, and processing had one of 9.2 cm⁻¹. Given this small increase and the lack of any large D peak on the spectra, it's likely that the processing has resulted in some small defects (very small D peak in the noise) which are likely related to grain formation (as the slight broadening of the G peak will be the result of a D′ peak similarly in the noise, i.e. A D/D′ ratio of ˜3.5).

FIG. 7. A comparison in the electrical resistance measurements of the graphene covered Si dies seen in FIGS. 3 and 5. Here the resistance of the a) two step acetone-IPA and b) three step xylene-acetone-IPA cleaning methods can be seen. The left circle highlights the location of the die (as well as the location of the probes), while the top right circle highlights the resistance measurement. The measurement indicated in a) is too high for the range to measure, indicating a resistance over 100 MΩ (effectively an electrical insulator) far larger than expected for graphene. For b) an electrical resistance was detected (though was difficult to stabilise given the measurement methods used here) in the kΩ range, which is typical for graphene.

FIG. 8. Proposed solution for the delamination of graphene. A piece of bare Si (dark contrast rectangle/blue) with a SiO₂ (low contrast rectangle/grey) passivation layer is cleaned for graphene transfer (a). Graphene (dotted line) is transferred to the surface using a polymer (generally PMMA), after which the PMMA is removed (b). Contaminants, defects and amorphous carbon from synthesis and transfer remain on the graphene surface (c) are removed with a xylene clean, followed by acetone and IPA clean to remove any further xylene residue (d). This reduces potential anchor points for PMMA (e). Subsequently, when PMMA is removed, the graphene remains primarily intact (f).

FIG. 9. Graphene on Si die following xylene-acetone-IPA cleaning, e-beam lithography, Au deposition, and xylene strip off. Images show three different magnifications, showing that a) broadly graphene remains, b) graphene has been stripped off from areas where the gold was deposited and c) the graphene is continuous on the smallest scales, with minor defects.

FIG. 10. Graphene on Si die following xylene-acetone-IPA cleaning, e-beam lithography, graphene etches, another round of xylene-acetone-IPA cleaning, e-beam lithography, metal deposition, and xylene strip off. The image shows that the graphene sheet remains with connection to the metallic electrodes after multiple rounds of lithography.

FIG. 11. Graphene four probe measurement device on an Si die following xylene-acetone-IPA cleaning, e-beam lithography, graphene etches, another round of xylene-acetone-IPA cleaning, e-beam lithography, metal deposition, and xylene strip off, with a corresponding I-V trace. The image shows that the graphene sheet remains with connection to the metallic electrodes after multiple rounds of lithography. In this case the device has had successful removal of the polymer layer and was tested for current voltage characteristics.

FIG. 12. Proposed process in the fabrication of a gFET. First a graphene covered Si die or wafer is cleaned in xylene, then acetone, and finally IPA (a). Following this PMMA is spin coated and cured (b). E-beam lithography is then performed, and the resist is developed (c). The sample is O₂ etched, with the remaining PMMA resist removed in xylene, leaving behind small graphene sheets (d). After this, the steps shown in (a) and (b) are repeated, and another round of e-beam lithography and development are performed (e). Metal contacts are then deposited, which is usually an adhesive layer including Ti or Cr, followed by the electrode material generally Au (f). The metal covered resist is stripped leaving behind the drain, source and gate electrodes (g). this completes the gFET, however, to make it suitable for biosensing, a passivation layer is required. Once again step (a) and (b) is performed before another e-beam lithography step, before a di-electric material is deposited (h). A final strip off step leaves only the graphene and gate electrodes exposed (i).

### DETAILED DESCRIPTION

Presently in the art one of the most basic cleaning methods used in cleanrooms is the use of ketones and alcohols. The present inventors have found that the additional cleaning with a methylbenzene (e.g. xylene) is able to improve the graphene layer in terms of minimising delamination and/or defects.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The term “about” or “approximately” as used herein means within an acceptable error range for the particular value as determined by one of ordinary skill in the art, which will depend in part on how the value is measured or determined, i.e., the limitations of the measurement system.

Unless defined otherwise, all technical and scientific terms used herein have the same meaning as commonly understood by those of ordinary skill in the art to which the invention belongs. For the purposes of the present invention, the following terms are defined below.

In one aspect the invention provides a method of minimising or preventing graphene delamination and/or reducing defects on a graphene layer deposited on SiO₂/Si substrate, said method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited layer with a methylbenzene;
iv) cleaning the layer after step iii) with a ketone; and
v) cleaning the layer after step iv) with an alcohol.

In an embodiment the SiO₂/Si wafer substrate comprises a SiO₂ insulation layer of about 100 nm to 400 nm, for instance, about 100 nm, 150 nm, 200 nm, 250 nm, 300 nm, 350 nm, or about 400 nm (or any range between any two of the recited thicknesses).

Chemical vapour disposition (CVD) grown graphene is deposited on said wafer in a cleanroom environment (such as ISO5/Class 100 type).

As used herein “CVD grown graphene” refers to the technique of depositing graphene as a thin film onto a substrate (e.g. Cu or Ni foil) from vapour species through chemical reactions. The process and types of the various possible chemical reactions that occur in a CVD reactor are governed by many complex factors, including the system setup, reactor configuration, gas feedstock, gas ratios, both reactor pressure and gas partial pressures, reaction temperature, growth time, temperature, etc. CVD is an extensively used bottom-up approach for the synthesis of few-layer and single-layer graphene films. A variety of different CVD methods are available that can be employed to synthesise graphene-based materials. According to the characteristics of the processing parameters (pressure, temperature, precursor nature, gas flow state, wall/substrate temperature, depositing time, and activation manner), these methods can be categorised into seven main types based on temperature, pressure, wall/substrate, nature of precursor, depositing time, gas flow state and activation/power source.

While the CVD grown graphene is often regarded as high-quality graphene, which implies single crystalline material without contamination, wrinkle, cracks, or other defects. There is a required transfer step to deposit the graphene from the CVD grown graphene substrate on to the desired technological substrate, in the present case the SiO₂/Si wafer substrate.

The transfer is facilitated by polymer deposition transfer, with the aid of a polymer transfer agent such as polymethyl methacrylate (PMMA), poly(bisphenol A carbonate), or poly vinyl acetate (PVA).

As used herein, the polymer resist deposited on the graphene layer refers to a layer that acts as a temporary mask to protect underlying layers. In certain embodiments, the polymer resist is selected from the group consisting of poly(methyl methacrylate) (PMMA), poly(α-methyl styrene-co-α-chloroacrylate methylester) (CSAR62), ZEP520, and maN2403.

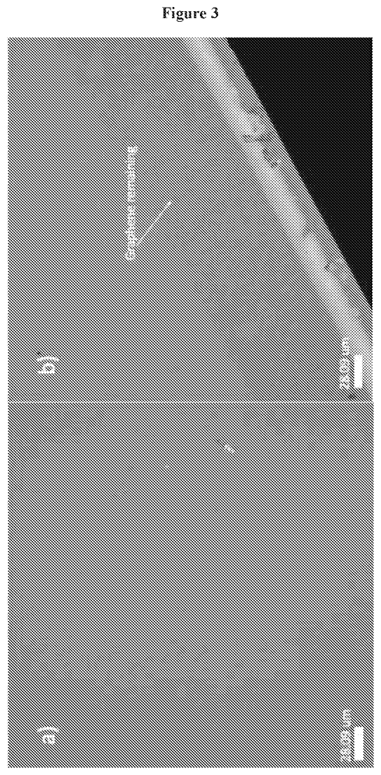

After graphene transfer, delamination and/or defects are commonly observed on the deposited graphene layer which degrade the quality of the graphene available for the application. This is illustrated in FIG. 3 c).

The sources of the defects and causes of delamination often come from sacrificial CVD grown graphene substrate (e.g. Cu foil); etchant used to dissolve the sacrificial substrate (e.g. ammonium persulfate (APS)); and the support layer (usually organic polymers such as polymethyl methacrylate (PMMA)) that also favours defect formations and produces the most undesirable type of residue owing to the compatible interaction of the polymers with graphene. These defects have a detrimental effect on graphene, mainly related to undesired doping that degrades the electrical and catalytic properties of graphene by creating charge-scattering centres and charge gradients.

Graphene layers are usually one atom or two atoms thick and as such cracking and delamination can easily occur as a result of mechanical strain applied during cleaning and repeated transfer, and damage from sharp tools. Such damage degrades the electrical properties and mechanical stability of the graphene, resulting in subsequent operational inefficiency or even failure. In addition, analysis of impure and damaged graphene makes it challenging to develop correct structure-property relationships.

The present inventors have found that the amount of defects and/or delamination can be minimised or avoided by cleaning the graphene deposited layer with a three-step method comprising a methylbenzene, a ketone, and finally an alcohol. With specific reference to the use of xylene the inventors have recognized that it has been only typically used as a developer in cleanrooms, as most polymers used are not as soluble in xylene as compared to other cleaners (e.g. acetone) and strippers (e.g. N-methyl-2-pyrrolidone). As such, using xylene as a cleaner and solvent has been overlooked. The inventors have identified xylene as being excellent for removing amorphous carbon deposits and being effective in the dissolution of polymer resists (particularly at thicknesses around and below a micron).

As used herein, the term “xylene” refers to dimethylbenzene and its three isomeric forms, i.e. 1,2-dimethylbenzene (ortho-xylene), 1,3-dimethylbenzene (meta-xylene) and 1,4-dimethylbenzene (para-xylene). Reference to xylene as used herein may refer to a single isomer of xylene, a mixture of two isomers of xylene or a mixture of all three isomers of xylene.

The present inventors have identified the following advantages of the defined methods:
a reduction in the degradation (i.e. delamination and/or defects) to graphene when patterned with polymer resists;
less complex (with fewer process steps and solvents) than methods using metal sacrificial layers;
current methods of residue removal are more time and energy intensive;
steps disclosed herein are easier to integrate into post fabrication processing (i.e. dicing);
xylene is not as strong a solvent as traditional removers/cleaners, so less risk of damage of graphene;
reduces the importance of perfecting the graphene synthesis and transfer methods, as defective additives can be removed.

Particular steps of embodiments of the present invention include:

a) Cleaning the Graphene Deposited Layer with a Methylbenzene.

This may involve washing the layer in the methylbenzene (e.g. xylene) by dispersion and gentle agitation for about 1 to about 5 minutes. This could be achieved either through use of a mechanical stirrer or manually swirling the solvent in a beaker. The cleaning may also be achieved by the mechanical means as wiping or aspirating the surface with the methylbenzene through pressure with an inert gas.

In certain embodiments, the layer is washed by dispersion in a methylbenzene. In certain embodiments, the layer is washed with gentle agitation in a methylbenzene. In certain embodiments, the layer is washed with a methylbenzene by agitation of the layer through the use of a mechanical stirrer. In certain embodiments, the layer is washed with a methylbenzene by manually swirling the methylbenzene in a suitable vessel. In other embodiments, the layer is washed for a time of between about 1 and about 5 minutes, for example, about 1, about 2, about 3, about 4 or about 5 minutes.

In certain embodiments, the layer is washed with a methylbenzene by mechanical means. In certain embodiments, the layer is washed with a methylbenzene by aspirating the surface of the layer with the methylbenzene through pressure with an inert gas. In other embodiments, the layer is washed with a methylbenzene by wiping the surface of the layer with the methylbenzene.

b) Cleaning the Layer after Step iii) with a Ketone.

This may involve washing the layer in ketone (e.g. acetone) by dispersion and gentle agitation for about 1 to about 7 minutes. This could be achieved either through use of a mechanical stirrer or manually swirling the solvent in a beaker. The cleaning may also be achieved by the mechanical means as wiping or aspirating the surface with the ketone through pressure with an inert gas.

In certain embodiments, the layer is washed by dispersion in a ketone. In certain embodiments, the layer is washed with gentle agitation in a ketone. In certain embodiments, the layer is washed with a ketone by agitation through the use of a mechanical stirrer. In certain embodiments, the layer is washed with a ketone by manually swirling the ketone in a suitable vessel. In other embodiments, the layer is washed for a time of between about 1 and about 10 minutes, for example, about 1, about 2, about 3, about 4, about 5, about 6 or about 7 minutes.

In certain embodiments, the layer is washed with a ketone by mechanical means. In certain embodiments, the layer is washed with a ketone by aspirating the surface of the layer with the ketone through pressure with an inert gas. In other embodiments, the layer is washed with a ketone by wiping the surface of the layer with the ketone.

c) Cleaning the Layer after Step iv) with an Alcohol.

This may involve washing the layer in an alcohol (e.g. IPA) by dispersion and gentle agitation for about 1 to about 5 minutes. This could be achieved either through use of a mechanical stirrer or manually swirling the solvent in a beaker. The cleaning may also be achieved by the mechanical means as wiping or aspirating the surface with the alcohol through pressure with an inert gas.

In certain embodiments, the layer is washed by dispersion in an alcohol. In certain embodiments, the layer is washed with gentle agitation in an alcohol. In certain embodiments, the layer is washed with an alcohol by agitation through the use of a mechanical stirrer. In certain embodiments, the layer is washed with an alcohol by manually swirling the alcohol in a suitable vessel. In other embodiments, the layer is washed for a time of between about 1 and about 5 minutes, for example, about 1, about 2, about 3, about 4 to about 5 minutes.

In certain embodiments, the layer is washed with an alcohol by mechanical means. In certain embodiments, the layer is washed with an alcohol by aspirating the surface of the layer with the alcohol through pressure with an inert gas. In other embodiments, the layer is washed with an alcohol by wiping the surface of the layer with the alcohol.

After each of these cleaning steps, or after all three cleaning steps, the graphene deposited layer is optionally dried with an inert gas such as nitrogen. In certain embodiments, the methods disclosed herein further include a drying step. In certain embodiments, the graphene-deposited layer is dried after cleaning with a methylbenzene. In other embodiments, the graphene-deposited layer is dried after cleaning with a ketone. In other embodiments, the graphene-deposited layer is dried after cleaning with an alcohol. In some embodiments, the graphene-deposited layer is dried after each cleaning step. In certain embodiments, the graphene-deposited layer is dried with nitrogen after cleaning with a methyl benzene. In other embodiments, the graphene-deposited layer is dried with nitrogen after cleaning with a ketone. In other embodiments, the graphene-deposited layer is dried with nitrogen after cleaning with an alcohol.

Although not necessary, the graphene layer may further undergo high temperature annealing or ICP based extra cleaning.

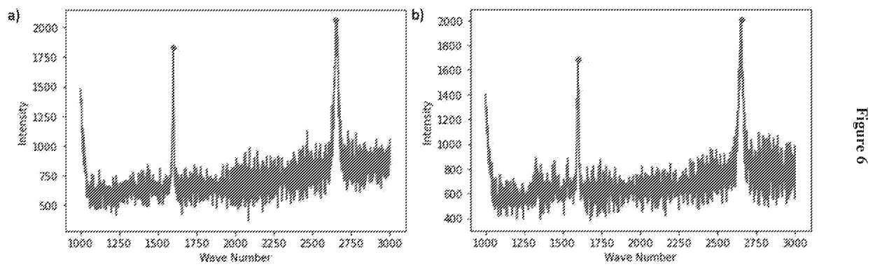

As stated above Raman spectroscopy may be used to quantify the number of defects on the deposited graphene layer. In this respect, the intensity of the graphitic peak at approximately 1600 cm⁻¹ (such as between 1605-1590 cm⁻¹, i.e. the G peak) is increased by at least 5% after the three cleaning steps compared to an equivalent graphene deposited layer which has only been cleaned by a ketone and alcohol (e.g. acetone and IPA) (see FIG. 6). The defects in the graphene layer may be quantified comparing the height of the D peak (about 1360 cm⁻¹), the height of the 2D peak (about 2650 cm⁻¹), the D/D′ ratio (i.e. the ratio between the peaks at about 1360 cm⁻¹ and 1610 cm⁻¹), and the ratio between D and G peaks, where each of these peaks are characteristic of graphene when analysed by Raman spectroscopy.

In an embodiment the D/D′ ratio of the graphene layer is less than 12 after the three cleaning steps compared to an equivalent graphene deposited layer which has only been cleaned by a ketone and alcohol (e.g. acetone and IPA).

In an embodiment the D/D′ ratio of the graphene layer is less than 11 after the three cleaning steps compared to an equivalent graphene deposited layer which has only been cleaned by a ketone and alcohol (e.g. acetone and IPA).

In an embodiment the D/D′ ratio of the graphene layer is less than 10 after the three cleaning steps compared to an equivalent graphene deposited layer which has only been cleaned by a ketone and alcohol (e.g. acetone and IPA).

In an embodiment the D/D′ ratio of the graphene layer is less than 9 after the three cleaning steps compared to an equivalent graphene deposited layer which has only been cleaned by a ketone and alcohol (e.g. acetone and IPA).

In an embodiment the D/D′ ratio of the graphene layer is less than 8 after the three cleaning steps compared to an equivalent graphene deposited layer which has only been cleaned by a ketone and alcohol (e.g. acetone and IPA).

In an embodiment the D/D′ ratio of the graphene layer is less than 7 after the three cleaning steps compared to an equivalent graphene deposited layer which has only been cleaned by a ketone and alcohol (e.g. acetone and IPA).

In an embodiment the D/D′ ratio of the graphene layer is less than 6 after the three cleaning steps compared to an equivalent graphene deposited layer which has only been cleaned by a ketone and alcohol (e.g. acetone and IPA).

In an embodiment the D/D′ ratio of the graphene layer is less than 5 after the three cleaning steps compared to an equivalent graphene deposited layer which has only been cleaned by a ketone and alcohol (e.g. acetone and IPA).

In an embodiment the D/D′ ratio of the graphene layer is less than 4 after the three cleaning steps compared to an equivalent graphene deposited layer which has only been cleaned by a ketone and alcohol (e.g. acetone and IPA).

In an embodiment the D/D′ ratio of the graphene layer is less than 3 after the three cleaning steps compared to an equivalent graphene deposited layer which has only been cleaned by a ketone and alcohol (e.g. acetone and IPA).

In an embodiment the D/D′ ratio of the graphene layer is less than 2 after the three cleaning steps compared to an equivalent graphene deposited layer which has only been cleaned by a ketone and alcohol (e.g. acetone and IPA).

In another embodiment the intensity of the graphitic peak at approximately 1600 cm⁻¹ is increased by at least 2% after the three cleaning steps compared to an equivalent graphene deposited layer which has only been cleaned by a ketone and alcohol (e.g. acetone and IPA).

In another embodiment the intensity of the graphitic peak at approximately 1600 cm⁻¹ is increased by at least 3% after the three cleaning steps compared to an equivalent graphene deposited layer which has only been cleaned by a ketone and alcohol (e.g. acetone and IPA).

In another embodiment the intensity of the graphitic peak at approximately 1600 cm⁻¹ is increased by at least 4% after the three cleaning steps compared to an equivalent graphene deposited layer which has only been cleaned by a ketone and alcohol (e.g. acetone and IPA).

In another embodiment the intensity of the graphitic peak at approximately 1600 cm⁻¹ is increased by at least 5% after the three cleaning steps compared to an equivalent graphene deposited layer which has only been cleaned by a ketone and alcohol (e.g. acetone and IPA).

In another embodiment the intensity of the graphitic peak at approximately 1600 cm 1 is increased by at least 6% after the three cleaning steps compared to an equivalent graphene deposited layer which has only been cleaned by a ketone and alcohol (e.g. acetone and IPA).

Other peaks characteristic to graphene may also be used to characterise the nature of the graphene and the extent of any defects present. For example, the peak at about 2650 cm⁻¹, i.e. the 2D peak, may be used. In this respect the intensity of the graphitic peak at approximately 2650 cm⁻¹ (such as between 2655-2645 cm⁻¹) is increased by at least 2% after the three cleaning steps compared to an equivalent graphene deposited layer which has only been cleaned by a ketone and alcohol (e.g. acetone and IPA).

In another embodiment the intensity of the graphitic peak at approximately 2650 cm⁻¹ is increased by at least 3% after the three cleaning steps compared to an equivalent graphene deposited layer which has only been cleaned by a ketone and alcohol (e.g. acetone and IPA).

In another embodiment the intensity of the graphitic peak at approximately 2650 cm⁻¹ is increased by at least 4% after the three cleaning steps compared to an equivalent graphene deposited layer which has only been cleaned by a ketone and alcohol (e.g. acetone and IPA).

In another embodiment the intensity of the graphitic peak at approximately 2650 cm⁻¹ is increased by at least 5% after the three cleaning steps compared to an equivalent graphene deposited layer which has only been cleaned by a ketone and alcohol (e.g. acetone and IPA).

In another embodiment the intensity of the graphitic peak at approximately 2650 cm⁻¹ is increased by at least 6% after the three cleaning steps compared to an equivalent graphene deposited layer which has only been cleaned by a ketone and alcohol (e.g. acetone and IPA).

In another embodiment the intensity of the graphitic peak at approximately 2650 cm⁻¹ is increased by at least 7% after the three cleaning steps compared to an equivalent graphene deposited layer which has only been cleaned by a ketone and alcohol (e.g. acetone and IPA).

In certain embodiments intensity of the graphitic peaks at approximately 1600 cm⁻¹ and approximately 2650 cm⁻¹ are both increased by at least 3% after the three cleaning steps compared to an equivalent graphene deposited layer which has only been cleaned by a ketone and alcohol (e.g. acetone and IPA).

In certain embodiments intensity of the graphitic peaks at approximately 1600 cm⁻¹ and approximately 2650 cm⁻¹ are both increased by at least 4% after the three cleaning steps compared to an equivalent graphene deposited layer which has only been cleaned by a ketone and alcohol (e.g. acetone and IPA).

In certain embodiments intensity of the graphitic peaks at approximately 1600 cm⁻¹ and approximately 2650 cm⁻¹ are both increased by at least 5% after the three cleaning steps compared to an equivalent graphene deposited layer which has only been cleaned by a ketone and alcohol (e.g. acetone and IPA).

Defects may also be determined using electronic measurements, specifically the conductivity and mobility of the prepared graphene can be used to determine the populations of total defects through the relation, μ=α/η₀. Measurement of μ and α is possible in a four-probe configuration for the measurement of a graphene sheet. Once these values are determined it is possible to calculate the defect density n₀.

In certain embodiments XPS data will have information about carbon compounds (i.e. how the graphene is arranged and what is on top of it) and information about other elements, particularly nitrogen and oxygen.

In this application the inventors focus on the ratio of C—C to C═C bonds, and the number of carbons at higher binding energies (i.e. looking for a decrease in the population of compounds between 286 and 289 eV)—with the penetration depth of the XPS being approximately 5 nm.

Also, for this application the inventors observe a lower percentage of nitrogen and oxygen in total terms (i.e. a lower atomic and/or weight percent) compared to graphene layers cleaned by comparable means. There is also the state that oxygen and nitrogen are in, whether they are bound to the carbon or just adsorbed. This information can also be taken from XPS. Measurements can be performed to show if these other elements are “electronically connected” to the graphene.

In certain embodiments the electrical resistance measurements taken of the graphene deposited layer cleaned with a methylbenzene (after PMMA removal), shows electrical resistance in a range close to graphene ˜450 Ohms/cm² (with the square being generally 1 cm×1 cm), compared to when a methylbenzene (e.g. xylene) clean is not part of the processing steps, the resistance is over 100 MΩ.

These methods are or have the potential to be, used in combination and/or production of:
graphene based electronic circuits;
graphene field effect transistors (gFETs);
gFETS as a basis for electronic sensors (gas/bio molecules);
analog circuits (amplifiers, oscillators and mixed circuits);
device miniaturisation to increase the number of devices on chip;
different graphene devices integrated into a single semiconductor chip;
with microfluidic delivery systems for gaseous/biological molecules; and
potential on-chip compatibility for device miniaturization and multiplexing.

For example, the invention further provides a method of fabricating a graphene field effect transistor (gFET) comprising a graphene layer deposited on SiO₂/Si substrate and wherein said gFET is characterised with at least one drain, source and gate electrodes, said method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited later with a methylbenzene;
iv) cleaning the layer after step iii) with a ketone;
v) cleaning the layer after step iv) with an alcohol;
vi) depositing a polymer resist on the layer after step v);
vii) defining areas where graphene will remain on wafer substrate using e-beam lithography;
viii) removing unneeded graphene using O₂ plasma etching;
ix) cleaning off any remaining polymer resist using a methylbenzene;
x) cleaning the remaining graphene layer with a ketone;
xi) cleaning the graphene layer after step x) with an alcohol;
xii) depositing an adhesive layer comprising Ti or Cr unto the graphene surface layer after step xi);
xiii) depositing a metal electrode material layer unto the adhesive layer after step xii); and
xiv) stripping the metal layer of step xiii) to form the gFET which comprises at least one each of a drain, source and gate electrodes.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Those skilled in the art will appreciate that the invention described herein in susceptible to variations and modifications other than those specifically described. It is to be understood that the invention includes all such variations and modifications which fall within the spirit and scope. The invention also includes all of the steps, features, compositions and compounds referred to or indicated in this specification, individually or collectively, and any and all combinations of any two or more of said steps or features.

### EXAMPLES

The following examples are illustrative of the disclosure and should not be construed as limiting in any way the general nature of the disclosure of the description throughout this specification.

### General Procedures

CVD grown graphene on a Si wafer (with a 300 nm SiO₂ insulation layer) was introduced to the cleanroom (ISO 5/Class 100). The graphene is grown on copper foils. Two-step process, first the copper foils are heated at ˜1000° C. for an hour at or slightly below latm, in an Ar-hydrogen flow (hydrogen ˜2.5%). Following this, graphene is grown for 15 minutes by adding 500 ppm of methane to the Ar hydrogen mixture.

The wafer was diced using a diamond scribe into roughly 1 cm×1 cm squares for all experiments. First the die was washed in xylene for 3 minutes with gentle agitation. Following this, the die was placed in acetone for another 5 minutes with gentle agitation to remove any organic residues. Finally, isopropanol (IPA) was used for a 3-minute rinse (again with gentle agitation) to remove any further residues. The die was then dried with a N₂ flow. An electron beam resist of 950 A4 polymethyl methacrylate (PMMA) was spin coated (Polos spin coater SPIN 150i) on top of the graphene on the die.

To demonstrate the effect of the xylene in cleaning, a separate process was also conducted involving only washing with acetone and IPA (for the same time and same conditions), before spin coating with a similar layer of PMMA.

Lithography was carried out with an Elionix F-125 electron beam lithography system. Electron beam voltage was set to 125 keV, while the dose for patterns varied from 1250 μC·cm⁻² for electrodes and markers (InA beam size), and 300 μC·cm⁻² for the graphene patterns (3 nA beam size). Development of the PMMA was conducted using methyl isobutyl ketone (MiBK) in IPA in a ratio of 1:3 (MiBK:IPA). PMMA was developed first in MiBK:IPA (for 40s in the case of the marker and electrode patterns, and 120s for the graphene pattern) before being rinsed in IPA (20 s for the marker and electrode patterns, and 60 s for the graphene pattern). The die is then dried in an N₂ stream.

The design of the markers, graphene and electrode layout was completed with Klayout and converted into a .con file using the Beamer software.

Graphene squares (of sizes 15 um×25 μm and 2 um×4 um) were formed via lithographically defining the areas, then etching the exposed graphene from the surface. Once this was achieved, graphene was etched using O₂ plasma with a reactive ion etcher (Southbay Technologies). Plasma was generated in 30 mT of O₂ with an RF power of 50 W, for a time of 1 min. This process was performed before Au marker deposition (ensuring Au deposition directly on SiO₂ layer), and to separate graphene sheet into multiple devices (following lithography for the graphene pattern).

Deposition of Au layer for markers and electrodes was achieved using an electron beam evaporator (AJA international). Au layers of 30 nm thickness (deposition rate of 1 A/s) were deposited on the marker (post plasma etching) and electrode lithography patterns. A Ti adhesion layer of 10 nm (deposition rate of 0.5 A/s) was first deposited prior to Au deposition.

### Example 1—Preparation and Characterisation of a Graphene Layer

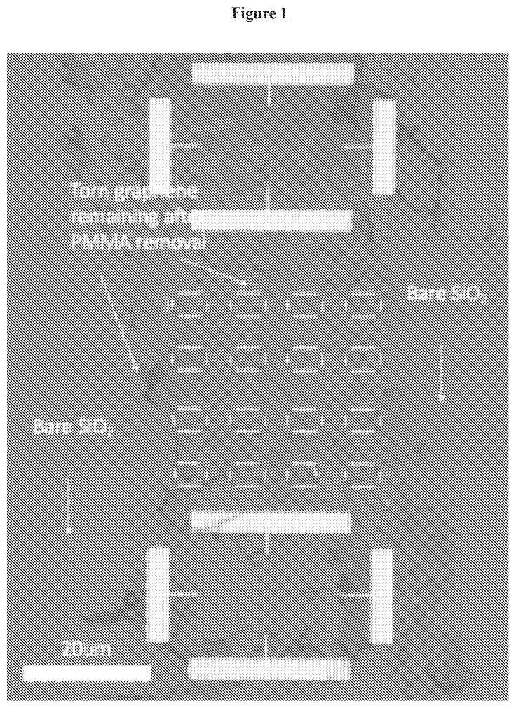

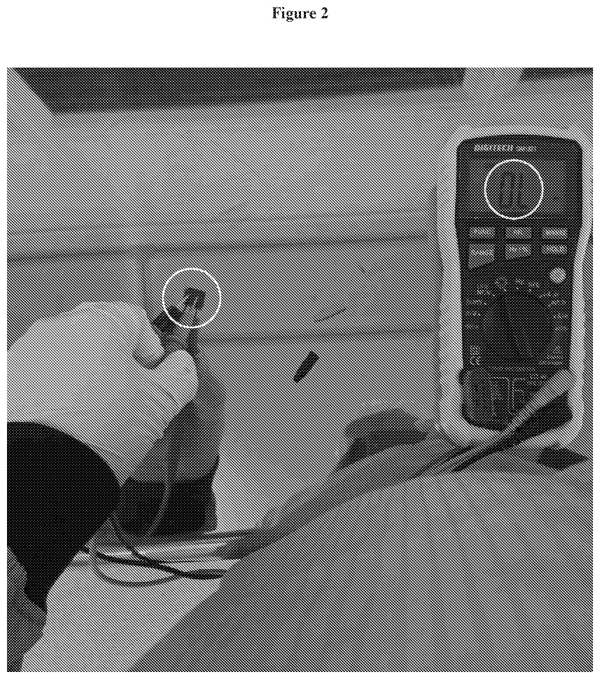

Graphene on SiO₂ was cleaned with acetone and IPA (not xylene) before lithography and metallisation. After stripping the residual gold and PMMA layer, it was found that the graphene been torn and removed from the SiO₂ substrate (see FIG. 1), leaving behind graphene localised mainly around the gold electrodes. While it appears that the electrodes hold the graphene to the substrate, this seems to just result in tearing of the graphene as it is removed with the PMMA. The global removal of graphene was electrically confirmed via resistance measurements (see FIG. 2). These measurements support the fact that there was a negligible amount of graphene remaining on the surface due to the high resistance (off the range>100MΩ).

The failure point was determined to occur during the PMMA deposition and curing. The substrates were cleaned with acetone and IPA before PMMA was spin coated and cured. Following curing, the PMMA was removed using acetone. The results of the removal can be seen in FIG. 3.

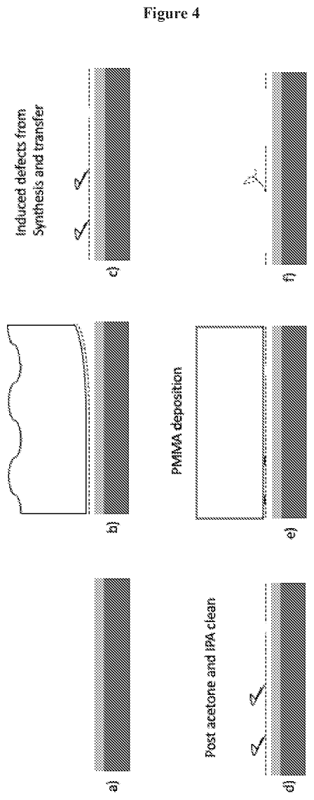

The images show that in the centre of the Si die, there is no graphene remaining (see FIG. 3a). Some graphene can still be seen around the edge (see FIG. 3b); however, it is evident that acetone removes the graphene along with the PMMA. The reason for this could be due to the interactions between the defective amorphous carbon on the graphene. The curing step could then improve the bonding between PMMA and graphene at the expense of the bonding between graphene and SiO₂. Given that some graphene remains around the gold (see FIG. 1), it could be possible that the electron beam is releasing the graphene from the PMMA during lithography. A brief scheme of the tearing and delamination process can be seen in FIG. 4.

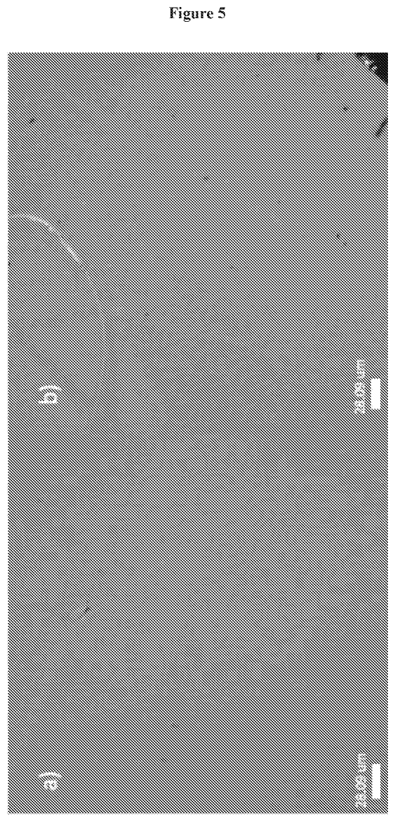

To remove the amorphous carbon, the process was altered, including xylene prior to the use of acetone and IPA processing steps. The aim was to remove any amorphous carbon with the xylene, while the acetone is used to remove organic residues. IPA cleaning is used further to remove residues left by the acetone. Following this, PMMA was deposited, cured, and then removed. The results can be seen in FIG. 5. The surface is mostly uniform except for some scratches, which suggest that the graphene layer remains uniformly intact. The edge (FIG. 5. b) shows more scratches in the surface, but clearly highlights how much more graphene is present in comparison to processing involving only acetone and IPA reactions. A Raman spectrum (see FIG. 6) confirmed that the graphene remained present following the process (see FIG. 6b). A comparison with the Raman spectrum prior to washing and PMMA deposition and removal (see FIG. 6a) shows that no major changes have occurred to the graphene. The lack of peaks in the D and D′ regions (1360 and 1610 cm⁻¹ respectively) show no defect created by the cleaning and PMMA removal, while the G and 2D regions (corresponding to 1600 and 2650 cm⁻¹) are almost identical in shape and ratio.

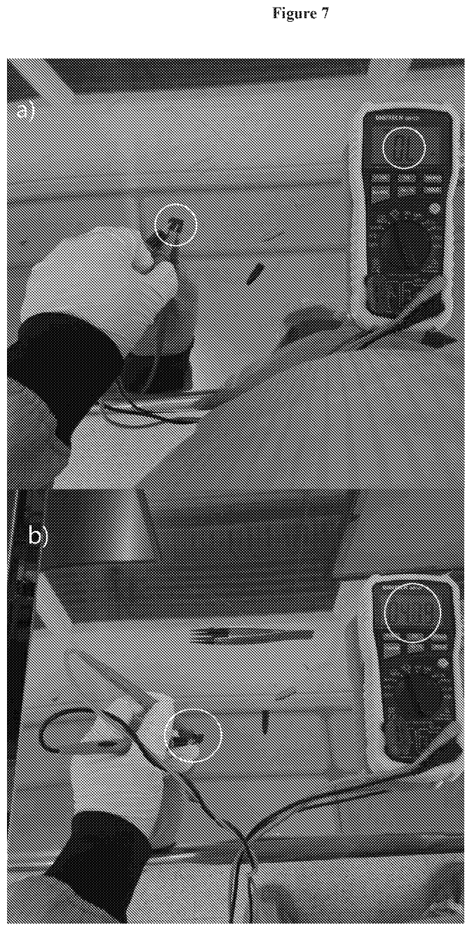

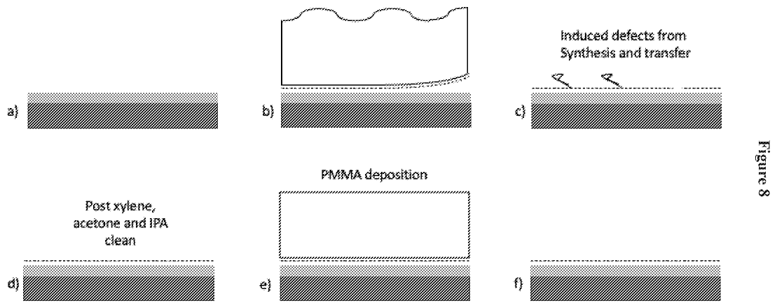

FIG. 7 shows a comparison between electrical resistance measurements taken of the graphene covered Si die after PMMA removal. The xylene cleaned graphene shows electrical resistance in a range close to graphene, while when xylene is not included in the processing steps the resistance is once again over 100MΩ. In the absence of xylene processing the graphene has been removed, confirming that the xylene processing method prevents the delamination of graphene. The proposed process is outlined in the scheme in FIG. 8. The difference between this scheme and the one presented in FIG. 4 is that the xylene is proposed to remove the amorphous carbon growth and smooth out some of the defects caused during growth, transfer or storage.

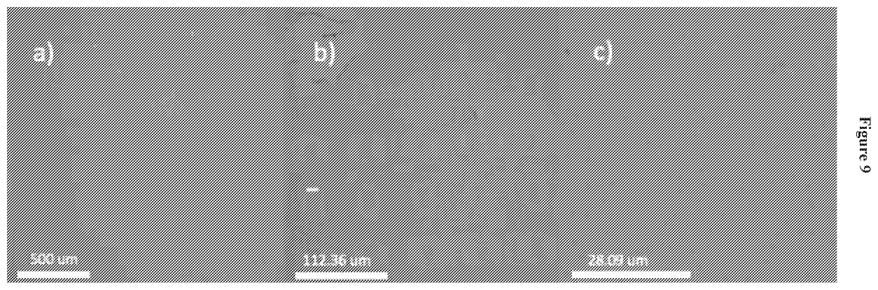

The xylene-acetone-IPA cleaning was integrated into a lithography process and Au electrodes were deposited on the graphene surface. Au was then stripped off using xylene at 80° C. FIG. 8 shows the results of this strip. The graphene remains intact except around the area where the Au was deposited (see FIG. 9a). This graphene tearing is caused by the Au being stripped off (see FIG. 9b) as shown by the pattern which remains in the graphene. A likely cause for the graphene tearing is that the Au electrodes became more tightly bound to the graphene during the deposition due to the temperature of the inbound metal. A high magnification image of the graphene shows that it is continuous, however, there are some defects which need to be considered (either in establishing a baseline or optimise to reduce them).

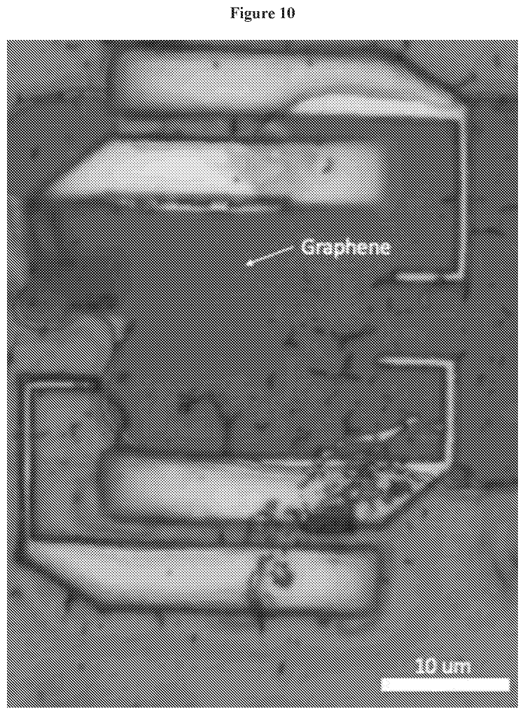

Given that the Au initiated graphene tearing, another process was performed (employing xylene-acetone-IPA cleaning) starting with graphene etching (allowing better contact better contacts and SiO₂, reducing the possibility of graphene being removed with the metal strip off), then depositing the contacts. The results can be seen in FIG. 10. While there are positive aspects to this proposed processing, for example the metal remains well bonded to the SiO₂ and the graphene has been etched well with the plasma. However complications can arise during fabrication. For example, reliability issues with the e-beam system may unexpectedly result in the inhomogeneous deposition of excess metal. This results in an ineffective removal (also referred to as ‘lift-off’). However, the etched graphene sheets can be seen where the resist has been successfully removed.

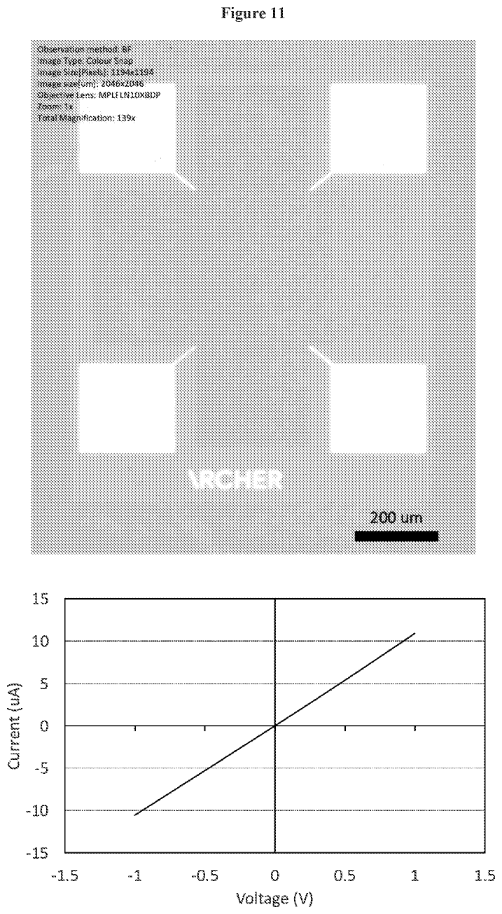

This process was used to create a four-probe graphene device to specifically test the electrical properties of graphene, including current and voltage (I-V) measurements (which can be used to determine the resistance of the graphene), as well as the conductivity and electron mobility. This can be seen in FIG. 11. Preliminary I-V measurements found a probe-to-probe resistance of ˜9.3 k≤2.

### Example 2—Preparation of a gFET

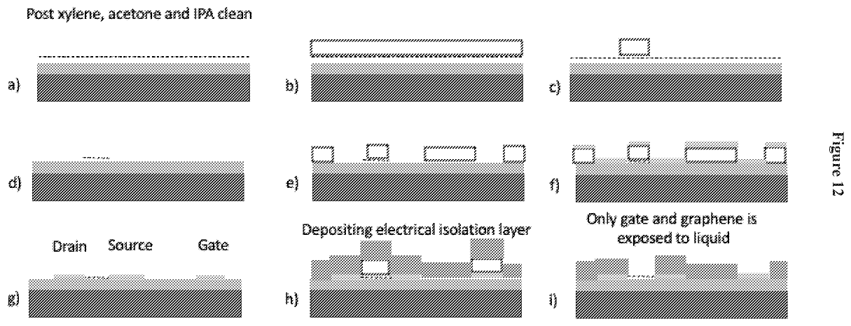

This process can be used in the fabrication of gFETs (which can then in turn be used in the construction of biosensors and gas sensors). A process which can be applied to fabricate gFETs is shown in FIG. 12. First the graphene on Si is cleaned with the three-step xylene-acetone-IPA process. Following this, PMMA is deposited, spin coated and cured (under the conditions described above). E-beam lithography is then used to define areas where the areas requiring graphene will remain, before O₂ plasma etching is used to remove most of the unneeded graphene. Following this, the remaining PMMA resist is removed with xylene. Another round of lithography follows, starting once again with the three-step cleaning process, after which PMMA is deposited and cured, with e-beam lithography being used to define the metal contact areas. Metal layers are then deposited using evaporation methods. There is usually two layers, a thinner adhesion layer (typically consisting of Ti or Cr) and the thicker electrode layer (typically composed of Au). The resist-metal layer is then stripped from the surface using xylene. To function as a liquid gated gFET, surface passivation is required to prevent shorts (and in the case of biosensors to avoid cross-talk in multiplexed designs). This is achieved by another lithography process, and the deposition of a di-electric material (for e.g. SiN is used preferentially to prevent ion transfer). When the resist and di-electric material are stripped, again with xylene, the only areas exposed which are not di-electric are the gate electrodes and the graphene.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

Throughout this specification and the claims which follow, unless the context requires otherwise, the phrase “consisting essentially of”, and variations such as “consists essentially of” will be understood to indicate that the recited element(s) is/are essential i.e. necessary elements of the invention. The phrase allows for the presence of other non-recited elements which do not materially affect the characteristics of the invention but excludes additional unspecified elements which would affect the basic and novel characteristics of the method defined.

1. A method of minimising or preventing graphene delamination and/or reducing defects on a graphene layer deposited on SiO₂/Si substrate, said method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited layer with a methylbenzene;
iv) cleaning the layer after step iii) with a ketone; and
v) cleaning the layer after step iv) with an alcohol.

2. A method of fabricating a graphene field effect transistor (gFET) comprising a graphene layer deposited on SiO₂/Si substrate and wherein said gFET is characterised with at least one drain, source and gate electrodes, said method comprising the steps of:
i) providing a SiO₂/Si wafer substrate;
ii) depositing a CVD (chemical vapour disposition) grown graphene layer to the surface of said wafer substrate by polymer deposition transfer;
iii) cleaning the graphene deposited later with a methylbenzene;
iv) cleaning the layer after step iii) with a ketone;
v) cleaning the layer after step iv) with an alcohol;
vi) depositing a polymer resist on the layer after step v);
vii) defining areas where graphene will remain on wafer substrate using e-beam lithography;
viii) removing unneeded graphene using O2 plasma etching;
ix) cleaning off any remaining polymer resist using a methylbenzene;
x) cleaning the remaining graphene layer with a ketone;
xi) cleaning the graphene layer after step x) with an alcohol;
xii) depositing an adhesive layer comprising Ti or Cr unto the graphene surface layer after step xi);
xiii) depositing a metal electrode material layer unto the adhesive layer after step xii); and
xiv) stripping the metal layer of step xiii) to form the gFET which comprises at least one each of a drain, source and gate electrodes.

3. A method according to claim 1, wherein the methylbenzene is selected from xylene (ortho-xylene, meta-xylene, or para-xylene), toluene, hemellitene (1,2,3-trimethylbenzene), mesitylene (1,3,5-trimethylbenzene), pseudocumene (1,2,4-trimethylbenzene), prehnitene (1,2,3,4-tetramethylbenzene), isodurene (1,2,3,5-tetramethylbenzene), durene (1,2,4,5-tetramethylbenzene), or hexamethylbenzene.

4. A method according to claim 1, wherein the methylbenzene is xylene.

5. A method according to claim 1, wherein the ketone is selected from acetone, ethyl acetate, cyclohexanone, methyl ethyl, or diacetone.

6. A method according to claim 1, wherein the ketone is acetone.

7. A method according to claim 1, wherein the alcohol is selected from isopropanol (IPA), n-propanol, n-butanol, isobutanol, tert-butanol, or n-pentanol.

8. A method according to claim 1, wherein the alcohol is isopropanol (IPA).

9. A method according to claim 2, wherein the polymer resist is PMMA.

10. A graphene layer prepared according to a method as defined in claim 1.

11. A graphene field effect transistor (gFET) prepared according to a method as defined in claim 2.

12. A graphene field effect transistor according to claim 11, wherein the resistance of the graphene deposited layer is in a range characteristic of graphene.

13. A graphene field effect transistor according to claim 11, wherein the resistance of the graphene deposited layer is about 450 Ohm/cm².

14. An electronic device comprising a graphene layer as defined in claim 10.

15. An electronic device according to claim 14, wherein the device is selected from the group consisting of a graphene-based electronic circuit, an electronic sensor, an analog circuit, a semiconductor chip and a microfluidic delivery system.

16. An electronic device according to claim 15, wherein the graphene-based electronic circuit comprises a graphene field effect transistor (gFET).

17. An electronic device according to claim 15, wherein the electronic sensor is a sensor for a gas or a biological molecule.

18. An electronic device according to claim 15, wherein the analog circuit is an amplifier, an oscillator or a mixed circuit.

19. An electronic device according to claim 15, wherein the microfluidic delivery system delivers a gas and/or a biological molecule.
